(19) United States
(12) Patent Application Publication
(10) Pub. No.: US 2026/0039282 A1
(43) Pub. Date: Feb. 5, 2026

(54) PHASE AND DUTY CYCLE TRIM FOR MULTI-PHASE CLOCKING

(71) Applicant: Micron Technology, Inc., Boise, ID (US)

(72) Inventors: Tyler J. Gomm, Boise, ID (US); Yasuo Satoh, Tsukuba (JP)

(21) Appl. No.: 19/222,447

(22) Filed: May 29, 2025

Related U.S. Application Data
(60) Provisional application No. 63/679,462, filed on Aug. 5, 2024.

(51) Int. Cl. H03K 5/13; G11C 7/22; H03K 7/08

(52) U.S. Cl. CPC H03K 5/13; G11C 7/222; H03K 7/08

(57) ABSTRACT

Systems and methods are provided for generating timing control signals for phase and duty cycle trimming to reduce or eliminate a quadrature error of a clock signal in a memory device. The memory device employs a trim circuit to perform phase tuning to reduce or eliminate the quadrature error. Different phase tuning settings are used by the trim circuit for different types of quadrature errors. The trim circuit adjusts different phases of the clock signal independently or dependently based on the phase tuning settings.

### CROSS-REFERENCE TO RELATED APPLICATIONS

This application claims priority to U.S. Provisional Application No. 63/679,462, filed Aug. 5, 2024, which is incorporated by reference herein in its entirety.

### BACKGROUND OF THE INVENTION

### Field Of The Invention

The present invention relates generally to the field of memory devices. More specifically, embodiments of the present disclosure relate to phase and duty cycle trimming for multi-phase clocking in memory devices.

### Description Of The Related Art

This section is intended to introduce the reader to various aspects of art that may be related to various aspects of the present invention, which are described and/or claimed below. This discussion is believed to be helpful in providing the reader with background information to facilitate a better understanding of the various aspects of the present invention. Accordingly, it should be understood that these statements are to be read in this light, and not as admissions of prior art.

Memory devices are widely used to store information related to various electronic devices such as computers, wireless communication devices, cameras, digital displays, and the like. Memory devices are frequently provided as internal memory, integrated circuits and/or external removable devices in computers or other electronic devices. There are many different types of memory, including volatile and non-volatile memory. Volatile memory, including random access memory (RAM), static random access memory (SRAM), dynamic random access memory (DRAM), and synchronous dynamic random access memory (SDRAM), among others, may require a source of applied power to maintain its data. Non-volatile memory, by contrast, may retain its stored data even when not externally powered. Non-volatile memory is available in a wide variety of technologies, including flash memory (e.g., NAND and NOR) phase change memory (PCM), ferroelectric random access memory (FeRAM), resistive random access memory (RRAM), and magnetic random access memory (MRAM), among others.

A memory device may include a number of storage elements, such as memory cells. Memory cells of a binary memory device may, for example, include a charged or discharged capacitor. A charged capacitor of a memory cell may, however, become discharged over time through leakage currents, resulting in the loss of the stored information. Certain features of volatile memory may offer performance advantages, such as faster read or write speeds, while features of non-volatile memory, such as the ability to store data without periodic refreshing, may be advantageous. Some of the memory devices include memory cells that may be accessed by turning on a transistor that couples the memory cell (e.g., the capacitor) with a wordline or a bitline/digit line. Different memory devices may use different architectures for arranging the memory cells. For example, different memory devices may arrange the memory cells in 2-dimensional or 3-dimensional rows and columns. A memory cell may be accessed (e.g., by using access commands such as read/write) based on activating a row and a column of the memory device corresponding to the memory cell.

Clock signals may be used in the memory device for controlling commands (e.g., read/write) and transferring data. As may be appreciated, the higher the frequency of the clock signals in the memory device, the more challenging it is to propagate the clock signals in the memory device within the prescribed timing requirements. In some embodiments, a divided multi-phase clocking scheme may be used in the memory device to divide a full frequency clock signal into multiple clock signals having a lower frequency with different phases (e.g., two phases, four phases). However, errors may occur to the clock signals due to device variation, power supply mismatch, etc. The proper operation of the memory device is based on correct timing of the command signals and data transferring. Accordingly, it is desirable to reduce or eliminate the errors of the clock signals.

### BRIEF DESCRIPTION OF THE DRAWINGS

Various aspects of this disclosure may better be understood upon reading the following detailed description and upon reference to the drawings in which:

FIG. 1 is a block diagram illustrating certain features of a memory device, according to an embodiment of the present disclosure;

FIG. 2 is a simplified block diagram illustrating an embodiment of a portion of the memory device of FIG. 1 that includes a trim circuit, according to an embodiment of the present disclosure;

FIG. 3 is a circuit diagram of an embodiment of a portion of the trim circuit of FIG. 2, according to an embodiment of the present disclosure;

FIGS. 4A-4C include timing diagrams for illustrating an embodiment of the phase tuning using the trim circuit of FIG. 3, according to an embodiment of the present disclosure;

FIGS. 5A and 5B include timing diagrams for illustrating another embodiment of the phase tuning using the trim circuit of FIG. 3, according to an embodiment of the present disclosure; and

FIG. 6 is a flow diagram of a method for using the trim circuit to reduce or eliminate a quadrature error of a full-frequency clock signal for the memory device of FIG. 1, according to an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

A memory device may perform memory operations such as storing data (e.g., write operations) and retrieving stored data (e.g., read operations). For example, a computing system may include various system components including one or multiple memory devices. The system components may communicate data (e.g., data bits) to perform system operations. For example, the system may include one or more processing components, one or more memory devices, among other system components. In different embodiments, the computing system may be disposed on a single electronic chip or multiple electronic chips. Moreover, the computing system may be disposed on a single electronic device or multiple electronic devices positioned in proximity of or remote from each other.

The memory device may include a number of memory banks, controller circuitry, command decoder circuitry, and a clock circuit to provide the clock signal, among other memory components. In some cases, the controller circuitry (hereinafter, controller) may include the command decoder circuitry (hereinafter, command decoder). In alternative or additional cases, the command decoder may include separate circuitry disposed between the controller and the memory banks or any other viable location. The memory device may include control blocks associated with the memory banks. In some cases, the command decoder may provide the access instructions to the control blocks of the memory banks.

The proper operation of the memory device may be based on correct timing of the command signals and data transferring. In some embodiments, a divided multiple-phase clocking scheme may be used in the memory device to divide a full frequency clock signal into multiple clock signals having a lower frequency with different phases (e.g., two phases, four phases). However, errors may occur to the clock signals due to device variation, power supply mismatch, etc. For example a clock signal may have a quadrature error. Quadrature error is a phase-to-phase error and it is a duty cycle error of the clock signal, which means the clock signal may have a different duty cycle during a first clock cycle than a second clock cycle. Quadrature error (i.e., inconsistency in duty cycle) in a clock signal may result in data access errors.

The current disclosure herein provides a technology and methods related to phase and duty cycle trimming to reduce or eliminate a quadrature error of a clock signal in a memory device. The memory device may employ a trim circuit to perform phase tuning to reduce or eliminate the quadrature error. Different phase tuning settings may be used by the trim circuit for different types of quadrature errors. The trim circuit may adjust different phases of the clock signal independently or dependently based on the phase tuning settings.

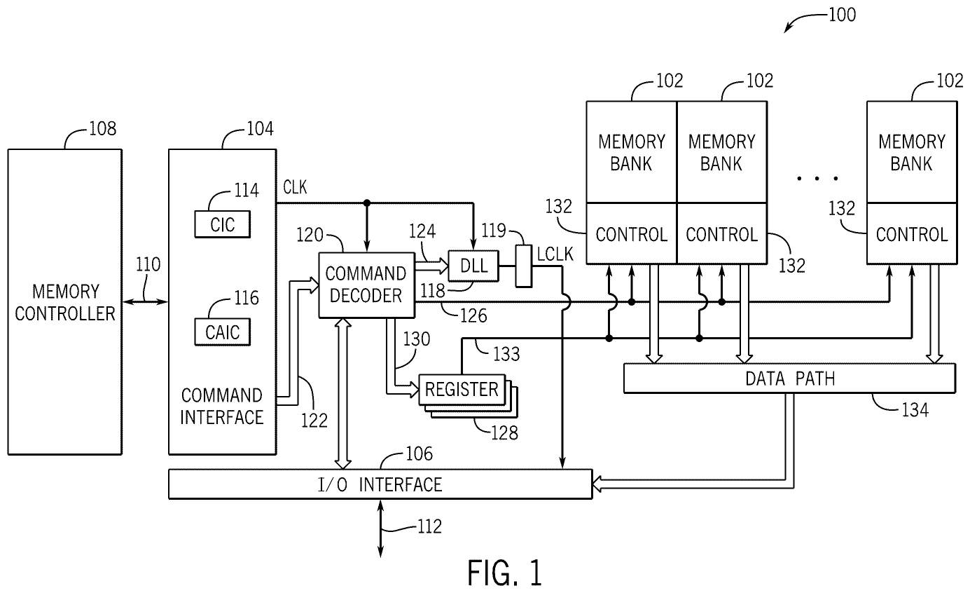

Turning now to the figures, FIG. 1 depicts a simplified block diagram illustrating certain features of a memory device 100 (e.g., a memory subsystem of an apparatus). Specifically, the block diagram of FIG. 1 depicts a functional block diagram illustrating certain functionality of the memory device 100. In accordance with one embodiment, the memory device 100 may include a random access memory (RAM) device, a ferroelectric RAM (FeRAM) device, a dynamic RAM (DRAM) device, a static RAM (SRAM) device (including a double data rate SRAM device), flash memory, and/or a 3D memory array including phase change (PC) memory and/or other chalcogenide-based memory, such as self-selecting memories (SSM). Moreover, each memory cell of such 3D memory array may include a corresponding logic storing device (e.g., a capacitor, a resistor, or the resistance of the chalcogenide material(s)).

The memory device 100 may include a number of memory banks 102 each including one or more memory arrays. Various configurations, organizations, and sizes of the memory banks 102 on the memory device 100 may be used based on an application and/or design of the memory device 100 within an electrical system. For example, in different embodiments, the memory banks 102 may include a different number of rows and/or columns of memory cells. Moreover, the memory banks 102 may each include a number of pins for communicating with other blocks of the memory device 100. For example, each memory bank 102 may receive one data bit per pin at each clock cycle. Furthermore, the memory banks 102 may be grouped into multiple memory groups (e.g., two memory groups, three memory groups).

The memory device 100 may also include a command interface 104 and an input/output (I/O) interface 106. The command interface 104 is configured to provide a number of signals received from a processor (e.g., a processor subsystem of an apparatus) or a controller, such as a memory controller 108. In different embodiments, the memory controller 108, hereinafter controller 108, may include one or more processors (e.g., memory processors), one or more programmable logic fabrics, or any other suitable processing components.

In some embodiments, a bus 110 may provide a signal path or a group of signal paths to allow bidirectional communication between the controller 108, the command interface 104 and the I/O interface 106. For example, the controller 108 may receive memory access requests from the I/O interface via the command interface 104 and the bus 110. Moreover, the controller 108 may provide the access commands and/or access instructions for performing memory operations to the command interface 104 via the bus 110.

Similarly, an external bus 112 may provide another signal path or group of signal paths to allow for bidirectional transmission of signals, such as data signals and access commands (e.g., read/write requests), between the I/O interface 106, the controller 108, a command decoder 120, and/or other components. Thus, the controller 108 may provide various signals (e.g., the access commands, the access instructions, or other signals) to different components of the memory device 100 to facilitate the transmission and receipt of data to be written to or read from the memory banks 102.

That said, the command interface 104 may receive different signals from the controller 108. For example, a reset command may be used to reset the command interface 104, status registers, state machines and the like, during power-up. Various testing signals may also be provided to the memory device 100. For example, the controller 108 may use such testing signals to test connectivity of different components of the memory device 100. In some embodiments, the command interface 104 may also provide an alert signal to the controller 108 upon detection of an error in the memory device 100. Moreover, the I/O interface 106 may additionally or alternatively be used for providing such alert signals, for example, to other system components electrically connected to the memory device 100.

The command interface 104 may also receive one or more clock signals from an external device (e.g., an external clock signal). Moreover, the command interface 104 may include a clock input circuit 114 (CIC) and a command address input circuit 116 (CAIC). The command interface 104 may use the clock input circuit 114 and the command address input circuit 116 to receive the input signals, including the access commands, to facilitate communication with the memory banks 102 and other components of the memory device 100. Moreover, the clock input circuit 114 may receive the one or more clock signals (e.g., the external clock signal) and may generate an internal clock signal (CLK) therefrom. In some embodiment, the CIC 114 may include a multi-phase clock divider (e.g., 4-phase clock divider) to divide a full frequency clock signal into multiple divided clock signals having a lower frequency with different phases (e.g., two phases, four phases), as described in detail herein.

In some embodiments, the command interface 104 may provide the CLK to the command decoder 120 and an internal clock generator, such as a delay locked loop (DLL) 118 circuit. The DLL 118 may generate a phase controlled internal clock signal (LCLK) based on the received CLK. For example, the DLL 118 may provide the LCLK to the I/O interface 106. Subsequently, the I/O interface 106 may use the received LCLK as a clock signal for transmitting the read data using the external bus 112.

In some embodiments, the memory device 100 may include a trim circuit 119 to trim the multiple divided clock signals (e.g., two phases, four phases) generated in the CIC 114. The trim circuit 119 may be used to adjust the phase-to-phase alignment among the multiple divided clock signals to reduce or eliminate the quadrature error of the full frequency clock signal. The adjusted multiple divided clock signals may be sent to the I/O interface 106 and used to reconstruct the full frequency clock signal.

The command interface 104 may also provide the internal clock signal CLK to various other memory components. As mentioned above, the command decoder 120 may receive the internal clock signal CLK. In some cases, the command decoder 120 may also receive the access commands via a bus 122 and/or through the I/O interface 106 received via the external bus 112. For example, the command decoder 120 may receive the access commands through the I/O interface 106 transmitted by one or more external devices. In some cases, a processor may transmit the access commands.

The command decoder 120 may decode the access commands and/or the memory access requests to provide corresponding access instructions for accessing target memory cells. For instance, the command decoder 120 may provide the access instructions to one or more control blocks 132 associated with the memory banks 102 via a bus path 126. In some cases, the command decoder 120 may provide the access instructions to the control blocks 132 in coordination with the DLL 118 over a bus 124. For example, the command decoder 120 may coordinate generation of the access instructions in-line (e.g., synchronized) with the CLK and/or LCLK. In some cases, the command decoder 120 may receive the access commands using a rising edge and/or a falling edge of the external clock signal. For example, a processor may transmit the access commands using a memory command protocol, such as a single clock cycle memory command protocol, or a multi-clock cycle memory command protocol. The processor may use a specific memory command protocol based at least in part on the number of pins of the memory device 100 or the I/O interface 106, the number of rows and/or columns of the memory banks 102, and the number of memory banks 102. Subsequently, the command decoder 120 may provide the access instructions to the memory banks 102 based on receiving and decoding the access commands.

Accordingly, the command decoder 120 may provide the access instructions to the memory banks 102 using one or multiple clock cycles of the CLK via the bus path 126. The command decoder 120 may also transmit various signals to one or more registers 128 via, for example, one or more global wiring lines 130. Moreover, the memory device 100 may include other decoders, such as row decoders and column decoders, to facilitate access to the memory banks 102, as discussed below.

In some embodiments, each memory bank 102 may include a respective control block 132. In some cases, each of the control blocks 132 may also provide row decoding and column decoding capability based on receiving the access instructions. Accordingly, the control block 132 may facilitate accessing the memory cells of the respective memory banks 102. For example, the control blocks 132 may include circuitry (e.g., logic circuitry) to facilitate accessing the memory cells of the respective memory banks 102 based on receiving the access instructions. For example, each memory bank 102 and/or corresponding control block 132 may include sense amplifiers for read operations of the memory cells of respective memory bank 102.

In some cases, the control blocks 132 may receive the access instructions and determine target memory banks 102 associated with the target memory cells. In specific cases, the command decoder 120 may include the control blocks 132. Moreover, the control blocks 132 may also provide timing control and data control functions to facilitate execution of different commands with respect to the respective memory banks 102.

Furthermore, the command decoder 120 may provide register commands to the one or more registers 128 to facilitate operations of one or more of the memory banks 102, the control blocks 132, and the like. For example, one of the one or more registers 128 may provide instructions to configure various modes of programmable operations and/or configurations of the memory device 100. The one or more registers 128 may be included in various memory devices to provide and/or define operations of various components of the memory device 100. The one or more registers 128 may communicate with the control blocks 132 via a bus path 133

In some embodiments, the one or more registers 128 may provide configuration information to define operations of the memory device 100. For example, the one or more registers 128 may include operation instructions for DRAMs, synchronous DRAMs, FeRAMs, chalcogenide memories (e.g., SSM memory, PC memory), or other types of memories. As discussed above, the one or more registers 128 may receive various signals from the command decoder 120, or other components, via the one or more global wiring lines 130.

In some embodiments, the one or more global wiring lines 130 may include a common data path, a common address path, a common write command path, and a common read command path. The one or more global wiring lines 130 may traverse across the memory device 100, such that each of the one or more registers 128 may couple to the global wiring lines 130. The additional registers may involve additional wiring across the memory device (e.g., die), such that the registers are communicatively coupled to the corresponding memory components.

The I/O interface 106 may include a number of pins (e.g., 7 pins) to facilitate data communication with external components (e.g., the processing component, such as a processor). Particularly, the I/O interface 106 may receive the access commands via the pins. Moreover, data stored on the memory cells of the memory banks 102 may be transmitted to and/or retrieved from the memory banks 102 over a data path 134. The data path 134 may include a plurality of bi-directional data buses to one or more external devices via the I/O interface 106. For certain memory devices, such as a Double Data Rate (DDR) 5 SDRAM memory device, the I/O signals may be divided into upper and lower bytes; however, such segmentation is not utilized in conjunction with other memory device types.

That said, in different embodiments, the memory device 100 may include additional or alternative components. That is, the memory device 100 may include additional or alternative components such as power supply circuits (for receiving external VDD and VSS signals), read/write amplifiers (to amplify signals during read/write operations), temperature sensors (for sensing temperatures of the memory device 100), etc. Accordingly, it should be understood that the block diagram of FIG. 1 is only provided to highlight certain functional features of the memory device 100 to aid in the subsequent detailed description.

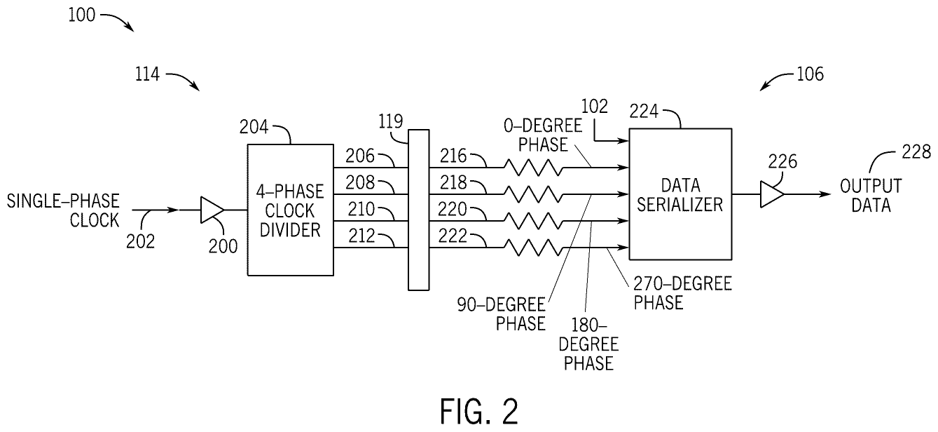

FIG. 2 is a simplified block diagram illustrating an embodiment of a portion of the memory device that includes the trim circuit 119. As illustrated, the CIC 114 may include a clock buffer circuit 200 to receive a single-phase clock signal 202 (e.g., from the memory controller 108 or a Register Clock Driver (RCD)). The CIC 114 may include a four-phase clock divider 204 to divide the single-phase clock signal 202 into four divided clock signals having different phases. For instance, the four divided clock signals may include a clock signal 206 having 0-degree phase, a clock signal 208 having 90-degree phase, a clock signal 210 having 180-degree phase, and a clock signal 212 having 270-degree phase. In some embodiments, the single-phase clock signal 202 may have a quadrature error, which may cause phase-to-phase misalignments among the four divided clock signals. The trim circuit 119 may include delay devices coupled to the four divided clock signals to adjust the phase-to-phase alignment among the four divided clock signals to reduce or eliminate the quadrature error of the single-phase clock signal.

In some embodiments, the quadrature error may be caused by errors (e.g., device variation, power supply mismatch) on the memory device 100 (e.g., on die) and is corresponding to a deterministic quadrature error, which may not change over time. In these embodiments, per-phase tuning may be used to independently adjust the phase-to-phase alignment among the four divided clock signals (e.g., via the delay devices coupled to each phase) to reduce or eliminate the deterministic quadrature error of the single-phase clock signal. For example, the Mode-Register Controlled Duty Cycle Adjust (MRDCA) defined in the DDR5 Joint Electron Device Engineering Council (JEDEC) specification allows per-phase tuning of the DRAM quadrature error.

In some embodiments, the quadrature error may be caused by errors not on the memory device 100 (e.g., off die) and is corresponding to non-deterministic quadrature error. In some embodiments, the per-phase tuning may not always obtain an expected result as the error is not deterministic and may change randomly. For non-deterministic quadrature error, tunings of several phases may be tied together (e.g., two-phase tuning) to adjust the phase-to-phase alignment among the four divided clock signals (e.g., via the delay devices coupled to each phase) to reduce or eliminate the non-deterministic quadrature error of the single-phase clock signal. For example, the tuning of the 90-degree phase clock signal and the tuning of the 270-degree phase clock signal may be tied together so that the tuning of the 270-degree phase clock signal may be the same as the tuning of the 90-degree phase clock signal. Moreover, the tuning of the 0-degree phase clock signal and the tuning of the 180-degree phase clock signal may be tied together so that the tuning of the 180-degree phase clock signal may be the same as the tuning of the 0-degree phase clock signal.

The per-phase tuning and the two-phase tuning may be selectable so that corresponding phase tuning may be selected to obtain better results when adjusting the phase-to-phase alignment among the four divided clock signals, thereby reducing or eliminating the quadrature error (deterministic, non-deterministic, or a combination of them) of the single-phase clock signal, as described in detail herein. For example, in some embodiments, the per-phase tuning may be used for the deterministic quadrature error and the two-phase tuning may be used for the non-deterministic quadrature error. In some embodiments, the two-phase tuning may be used for the deterministic quadrature error and non-deterministic quadrature error. In some embodiments, the quadrature error may be a combination of the deterministic quadrature error and the non-deterministic quadrature error, and the two-phase tuning may be used to reduce or eliminate the quadrature error.

The adjusted clock signals may be output from the trim circuit 119. For instance, an adjusted clock signal 216 corresponds to the clock signal 206, an adjusted clock signal 218 corresponds to the clock signal 208, an adjusted clock signal 220 corresponds to the clock signal 210, and an adjusted clock signal 222 corresponds to the clock signal 212. The adjusted clock signals may propagate in the memory device 100 and may be transmitted to a data serializer 224 in the I/O interface 106. The adjusted clock signals may be combined to generate a single-phase clock signal in the I/O interface 106, which may be used for controlling timing of operations (e.g., read, write) to the memory banks 102. For example, the data serializer 224 may receive read data from the memory banks 102 (e.g., via the data path 134) and store the read data in a data buffer 226, and the generated single-phase clock signal may be used to generate output data 228 from the data buffer 226.

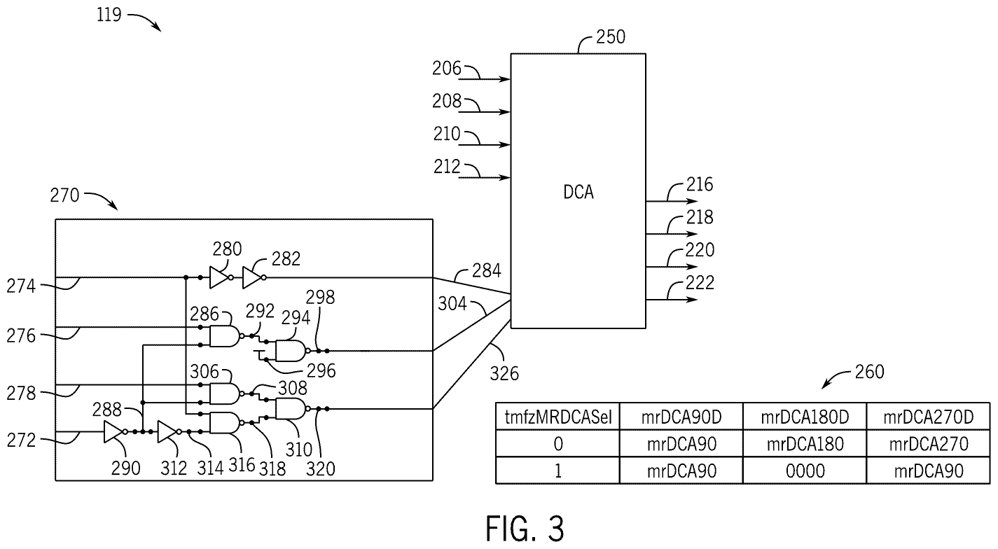

FIG. 3 illustrates an embodiment of a portion of the trim circuit 119. As illustrated, the trim circuit 119 may include a duty cycle adjuster (DCA) 250 to adjust the phase-to-phase alignment among the four divided clock signals 206, 208, 210, and 212 (e.g., via the delay devices coupled to each phase) to reduce or eliminate the quadrature error (deterministic, non-deterministic, or a combination of them). The output of the DCA 250 may include the adjusted clock signals 216, 218, 220, and 222.

As described above, the phase tuning may be selected based on the type of the quadrature error. For example, in some embodiments, the per-phase tuning may be selected for deterministic quadrature error, and, in some embodiments, the two-phase tuning may be selected for deterministic quadrature error, non-deterministic quadrature error, or combined quadrature error. A table 260 may be used to store the phase tuning settings for the DCA 250. Since the phase-to-phase alignments are relative phase adjustments among different phase clock signals (e.g., 0-degree, 90-degree, 180-degree, 270 degree), a certain phase clock signal (e.g., 0-degree, 90-degree) may be selected and used as the phase adjustment base signal (e.g., delay adjustment is zero) during the phase tuning and other phase clock signals may be adjusted relative to it. Accordingly, in the illustrated embodiment of table 260, only phase adjustments for clock signals having non-zero phases are listed since the phase adjustment for clock signal having 0-degree phase is zero. For instance, the phase adjustment for 90-degree phase clock signal (e.g., the clock signal 208) is mrDCA90, the phase adjustment for 180-degree phase clock signal (e.g., the clock signal 210) is mrDCA180, and the phase adjustment for 270-degree phase clock signal (e.g., the clock signal 212) is mrDCA270.

The table 260 may include a selection parameter, tmfzMRDCASel, having different values (e.g., 0, 1) corresponding to different phase tuning settings (e.g., per-phase, two-phase). When the selection parameter, tmfzMRDCASel, has a value of 0, the per-phase tuning setting may be selected and used in the DCA 250 to adjust the phase-to-phase alignment among the four divided clock signals 206, 208, 210, and 212. In the per-phase tuning setting, the DCA 250 may adjust the phase of the divided clock signals independently using the corresponding phase adjustments (e.g., mrDCA90D for 90-degree phase adjustment, mrDCA180D for 180-degree adjustment, mrDCA270D for 270-degree phase adjustment).

When the selection parameter, tmfzMRDCASel, has a value of 1, the two-phase tuning setting may be selected and used in the DCA 250 to adjust the phase-to-phase alignment among the four divided clock signals 206, 208, 210, and 212. In the two-phase tuning setting, the phase adjustment for the 180-degree phase clock signal in the DCA 250 is the same as the phase adjustment for the 0-degree phase clock signal (e.g., mrDCA180D=0); and, the phase adjustment for the 270-degree phase clock signal in the DCA 250 is the same as the phase adjustment for the 90-degree phase clock signal (e.g., mrDCA270D=mrDCA90D=mrDCA90). Accordingly, there are two sets of phase adjustments in the two-phase tuning setting, the first set of phase adjustment is for the 0-degree phase clock signal and the 180-degree phase clock signal, and the second set of phase adjustment is for the 90-degree phase clock signal and the 270-degree phase clock signal. It should be noted that, although, in the illustrated embodiment of table 260, the first set of phase adjustments is set to 0 and the second set of phase adjustments is used to adjust the phase-to-phase alignment among the multiple divided clock signals to reduce or eliminate the quadrature error, in other embodiments, the second set of phase adjustments may be set to 0 and the first set of phase adjustments may be used to adjust the phase-to-phase alignment among the multiple divided clock signals to reduce or eliminate the quadrature error.

The trim circuit 119 may include a control circuit 270 coupled to the DCA 250 to control the phase tuning method (e.g., per-phase, two-phase) used by the DCA 250 based on the phase tuning settings in the table 260. For instance, the control circuit 270 may receive a select signal 272 (e.g., generated by a fuse) carrying the value of the selection parameter (tmfzMRDCASel), which may have different values (e.g., 0, 1) corresponding to different phase tuning settings in the table 260, as described above. The control circuit 270 may receive a signal 274 carrying the value of the phase adjustment mrDCA90, a signal 276 carrying the value of the phase adjustment mrDCA180, and a signal 278 carrying the value of the phase adjustment mrDCA270.

The signal 274 may carry the value of mrDCA90 and transmit it (e.g., through an inverter 280 and an inverter 282) to an input 284 of the DCA 250, which corresponds to the value of mrDCA90D. Therefore, the input 284 may have the value of mrDCA90D regardless of the value of the signal 272 (tmfzMRDCASel), as illustrated in the table 260.

The signal 276 may be transmitted to a NAND logic gate 286 together with an inverted signal 288 of the signal 272, which is generated by an inverter 290. An output 292 of the NAND logic gate 286 may be input into another NAND logic gate 294 together with an always high input 296 (e.g., coupled to a high voltage VPERI). An output 298 of the NAND logic gate 294 may be transmitted to an input 304 of the DCA 250, which corresponds to the value of mrDCA180D. Accordingly, the value of the input 304 may be related to the value of the signal 272 and the value of the signal 276. When the signal 272 has a value of 0 (tmfzMRDCASel=0), the inverted signal 288 has a value of 1, and the output 292 may have the inversed value of the signal 276. Since the input 296 is 1, the output 298 may have the inversed value of the output 292. Accordingly, when the signal 272 has a value of 0 (tmfzMRDCASel=0), the output 298 may have the value of the signal 276, and the input 304 (mrDCA180D) may have the value of the signal 276 (mrDCA180), as illustrated in the table 260. When the signal 272 has a value of 1 (tmfzMRDCASel=1), the inverted signal 288 has a value of 0, and the output 292 may have a value of 1 regardless of the value of the signal 276. Since the input 296 is 1, the output 298 may have the inversed value of the output 292. Accordingly, when the signal 272 has a value of 1 (tmfzMRDCASel=1), the output 298 may have a value of 0 regardless of the value of the signal 276, and the input 304 (mrDCA180D) may have a value of 0 regardless of the value of the signal 276 (mrDCA180), as illustrated in the table 260.

The signal 278 may be transmitted to a NAND logic gate 306 together with the inverted signal 288 of the signal 272. An output 308 of the NAND logic gate may be input into a NAND logic gate 310. The inverted signal 288 may be transmitted into an inverter 312, and an output 314 of the inverter 312 may be input into a NAND logic gate 316 together with the signal 274. An output 318 of the NAND logic gate may be input into the NAND logic gate 310 with the output 308. An output 320 of the NAND logic gate 310 may be transmitted to an input 326 of the DCA 250, which corresponds to the value of mrDCA270D. Accordingly, the value of the input 326 may be related to the value of the signal 272, the value of the signal 274, and the value of the signal 278. When the signal 272 has a value of 0 (tmfzMRDCASel=0), the inverted signal 288 has a value of 1, the output 308 may have the inverted value of the signal 278, and the output 314 may have the value of the signal 272, which is 0. Accordingly, the output 318 may have a value 1 regardless of the value of the signal 274. Accordingly, the output 320 may have the inverted value of the output 308, which is the value of the signal 278, and the input 326 (mrDCA270D) may have the value of the signal 278 (mrDCA270), as illustrated in the table 260. When the signal 272 has a value of 1 (tmfzMRDCASel=1), the inverted signal 288 has a value of 0, the output 308 may have a value of 1 regardless of the value of the signal 278, and the output 314 may have the value of the signal 272, which is 1. Accordingly, the output 318 may have the inverted value of the signal 274. Accordingly, the output 320 may have the inverted value of the output 318, which is the value of the signal 274, and the input 326 (mrDCA270D) may have the value of the signal 274 (mrDCA90), as illustrated in the table 260.

Accordingly, the control circuit 270 may be used to control the phase tuning method (e.g., per-phase, two-phase) used by the DCA 250 based on the phase tuning settings in the table 260. In some embodiments, the phase adjustments (e.g., mrDCA90, mrDCA180, mrDCA270) may be calculated based on the quadrature error and stored in one or more mode registers (e.g., MR 43, MR44), and the phase adjustments used by the DCA 250 (e.g., mrDCA90D, mrDCA180D, mrDCA270D) may be determined according to the phase tuning settings in the table 260.

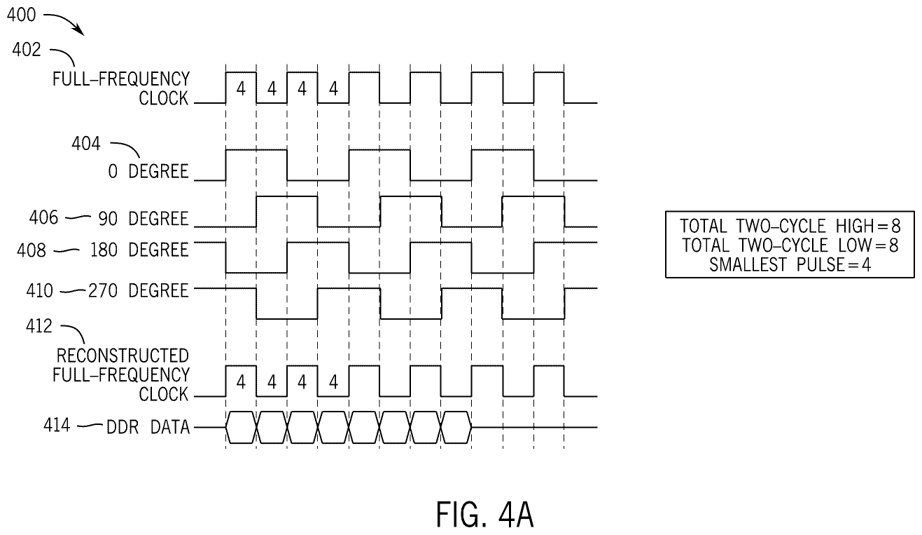

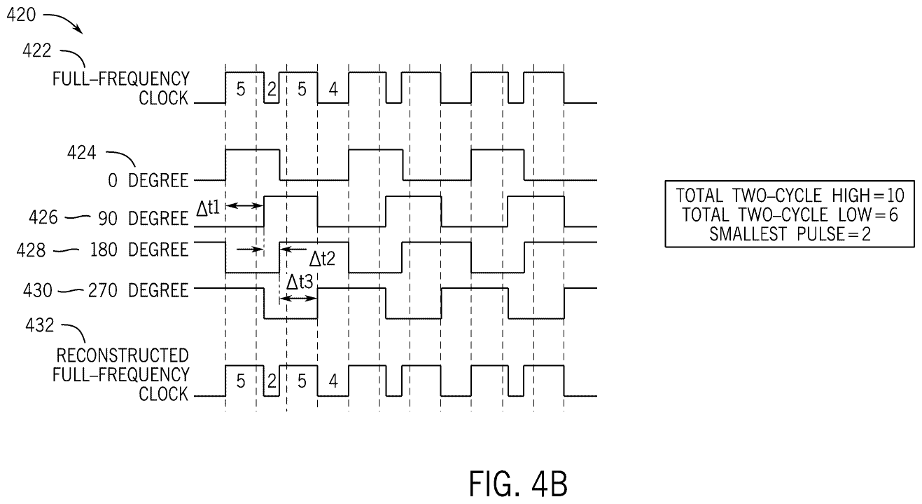

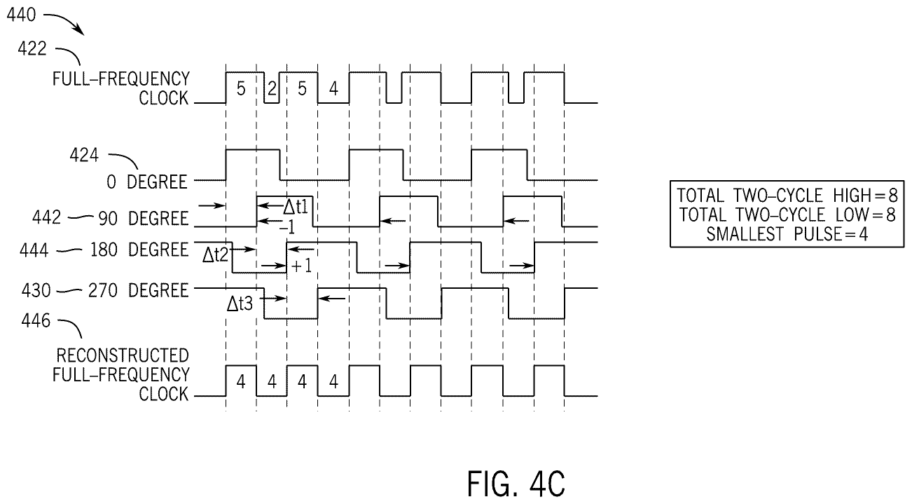

FIGS. 4A-4C include timing diagrams to illustrate an embodiment of the phase tuning using the trim circuit 119. A timing diagram 400 of FIG. 4A shows an embodiment of an ideal full-frequency clock signal 402 received by the CIC 114, which may include equal time for all pulses (e.g., 4 time unit) in any clock cycle. Accordingly, the total two-cycle (including both the first clock cycle and the second clock cycle) high corresponds to 8 time units and the total two-cycle low corresponds to 8 time units, with the smallest pulse including 4 time units. The full-frequency clock signal 402 may be divided (e.g., via the 4-phase cock divider 204) into four divided clock signals, including a clock signal 404 for 0-degree phase, a clock signal 406 for 90-degree phase, a clock signal 408 for 180-degree phase, and a clock signal 410 for 270-degree phase. The four divided clock signals may be used to obtain a reconstructed full-frequency clock signal 412 (e.g., by using the rising edges of corresponding pulses of the four divided clock signals). The reconstructed full-frequency clock signal 412 may include equal time period for all pulses (e.g., 4 time unit) in all clock cycles and may be used to generate output data (e.g., the output data 228). In some embodiments, the output data may be DDR data 414, in which data are transferred on both the rising edge and the falling edge of the reconstructed full-frequency clock signal 412. Accordingly, when there is a phase misalignment among the four divided clock signals, the reconstructed full-frequency clock signal 412 may not include equal time period for all pulses in all clock cycles, and the output data may not be generated correctly, as illustrated in detail herein.

In FIG. 4B, a timing diagram 420 shows an embodiment of a full-frequency clock signal 422 having a quadrature error, which may include unequal time periods for pulses in a clock cycle and may have different duty cycles in different clock cycles. For example, the first clock cycle of the clock signal 422 may include a high pulse lasting 5 time units and a low pulse lasting 2 time units, and the second clock cycle of the clock signal 422 may include a high pulse lasting 5 time units and a low pulse lasting 4 time units. Accordingly, the total two-cycle high corresponds to 10 time units and the total two-cycle low corresponds to 6 time units, with the smallest pulse including 2 time units. The full-frequency clock signal 422 may be divided (e.g., via the 4-phase cock divider 204) into four divided clock signals, including a clock signal 424 for 0-degree phase, a clock signal 426 for 90-degree phase, a clock signal 428 for 180-degree phase, and a clock signal 430 for 270-degree phase. As illustrated, the four divided clock signals may have phase-to-phase misalignments. For example, a time period Δt1 between the first rising edge of the signal 424 and the first rising edge of the signal 426 has a value of 5 time units (Δt1=5) instead of 4 time units as in the diagram 402. Similarly, a time period Δt2 between the first rising edge of the signal 426 and the first rising edge of the signal 428 has a value of 2 time units (Δt2=2) instead of 4 time units as in the diagram 402. Similarly, a time period Δt3 between the first rising edge of the signal 428 and the first rising edge of the signal 430 has a value of 5 time units (Δt3=5) instead of 4 time units as in the diagram 402. The four divided clock signals may be used to obtain a reconstructed full-frequency clock signal 432 (e.g., by using the rising edges of corresponding pulses of the four divided clock signals). Accordingly, the reconstructed full-frequency clock signal 432 may include unequal time periods for pulses in a clock cycle and may have different duty cycles in different clock cycles, as illustrated in FIG. 4B.

In some embodiments, the quadrature error of the full-frequency clock signal 422 may be a deterministic quadrature error (e.g., originated on die), and the per-phase tuning setting (tmfzMRDCASel=0) of the table 260 may be used by the trim circuit 119 to independently adjust the phase-to-phase alignment among the four divided clock signals (e.g., via the delay devices coupled to each phase) to reduce or eliminate the deterministic quadrature error of the full frequency clock signal 422, as illustrated in a diagram 440 of FIG. 4C. For example, since Δt1=5, the phase adjustment mrDCA90 may have a value of “−1” meaning adjusting the rising edges of the 90-degree phase clock signal 426 backward in time by 1 time unit, resulting in an adjusted 90-degree phase clock signal 442 with Δt1=5−1=4, as illustrated in the diagram 440. Similarly, the phase adjustment mrDCA180 may have a value of “+1” meaning adjusting the rising edges of the 180-degree phase clock signal 428 forward in time by 1 time unit, resulting in an adjusted 180-degree phase clock signal 444 with Δt2=2−(−1)+1=4. In the illustrated embodiment, mrDCA270 may have a value of 0 since Δt3=5−1=4, therefore the phase of the 270-degree phase clock signal 430 may not be adjusted. The adjusted clock signals 442 and 444 may be used together with the clock signals 424 and 430 to obtain a reconstructed full-frequency clock signal 452 (e.g., by using the rising edges of corresponding pulses of the four divided clock signals). The reconstructed full-frequency clock signal 446 may include equal time periods for all pulses (e.g., 4 time unit) in all clock cycles and may be used to generate output data (e.g., the output data 228). Accordingly, the deterministic quadrature error of the clock signal 422 may be corrected by using the per-phase setting of the table 260.

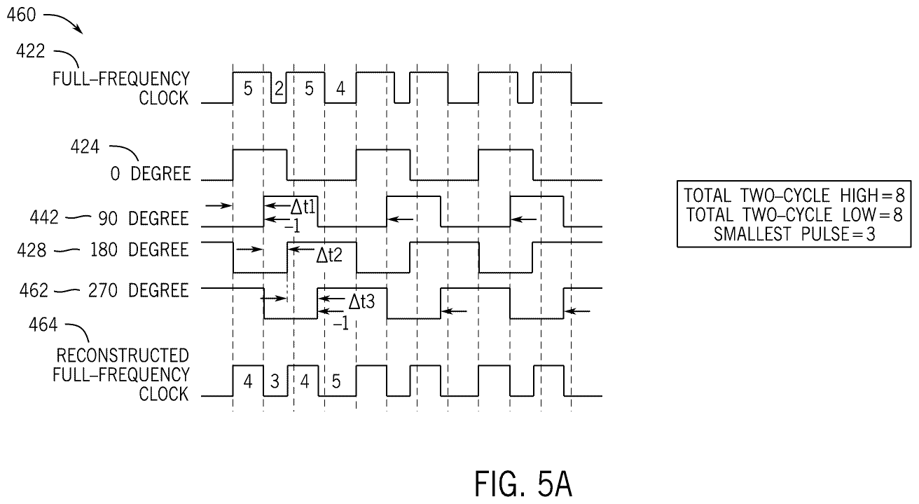

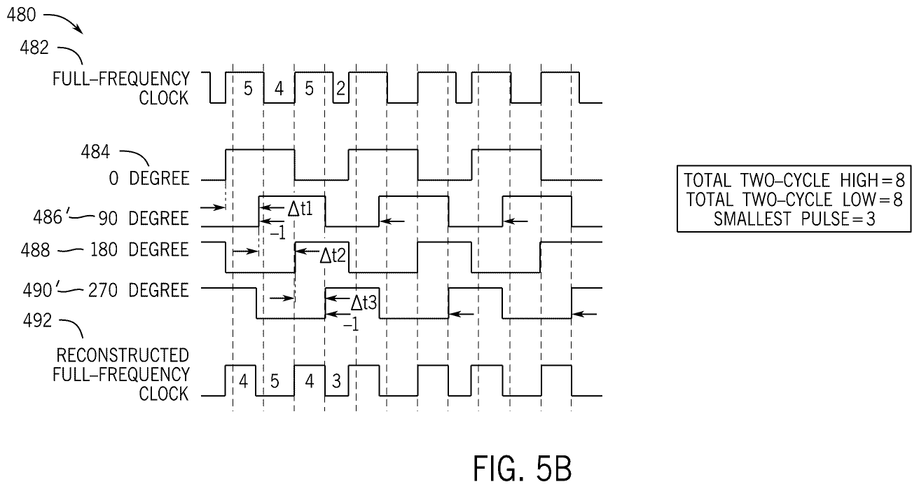

FIGS. 5A and 5B include timing diagrams to illustrate another embodiment of the phase tuning using the trim circuit 119. As discussed above, the per-phase tuning setting (tmfzMRDCASel=0) of the table 260 may be used by the trim circuit 119 to adjust the phase-to-phase alignment among the four divided clock signals (e.g., via the delay devices coupled to each phase) to reduce or eliminate the deterministic quadrature error of the full frequency clock signal 422. In some embodiments, the two-phase tuning setting (tmfzMRDCASel=1) of the table 260 may also be used by the trim circuit 119 to adjust the phase-to-phase alignment among the four divided clock signals to reduce or eliminate the deterministic quadrature error of the full frequency clock signal 422, as illustrated in a diagram 460 of FIG. 5A. According to the table 260, the phase adjustment mrDCA90D is the same for the per-phase tuning and the two-phase tuning, with Δt1=5−1=4, as illustrated in the diagram 460. For the two-phase tuning, the phase adjustment for 180-degree phase clock signal is the same as the phase adjustment for 0-degree phase clock signal (e.g., mrDCA180D=0), therefore, the clock signal 428 may be unadjusted with Δt2=2−(−1)=3. According to the table 260, the phase adjustment mrDCA270D is the same as the phase adjustment mrDCA90D, therefore, an adjusted 270-degree phase clock signal 462 may be obtained by adjusting the rising edges of the 270-degree phase clock signal 430 backward in time by 1 time unit with Δt3=5−1=4, as illustrated in the diagram 460. The adjusted clock signals 442 and 462 may be used together with the clock signals 424 and 428 to obtain a reconstructed full-frequency clock signal 464 (e.g., by using the rising edges of corresponding pulses of the four divided clock signals). The first clock cycle of the reconstructed full-frequency clock signal 464 may include a high pulse lasting 4 time units and a low pulse lasting 3 time units, and the second clock cycle of the clock signal 422 may include a high pulse lasting 4 time units and a low pulse lasting 5 time units. Therefore, the total two-cycle high corresponds to 8 time units and the total two-cycle low corresponds to 8 time units, with the smallest pulse including 3 time units. Accordingly, the reconstructed full-frequency clock signal 464 may have improved phase and duty cycle compared to the clock signal 422. Since the deterministic quadrature error may not change, the trim circuit 119 may continue using the same phase adjustments to improve the phase and the duty cycle of the clock signal.

In some embodiments, the quadrature error of the full-frequency clock signal 422 may be a non-deterministic quadrature error (e.g., originated off die), and may change randomly, as illustrated in a diagram 480 of FIG. 5B. For example, the clock cycles of the full-frequency clock signal 422 may be swapped (e.g., the first clock cycle is switched with the second clock cycle), resulting in a full-frequency clock signal 482. The same phase adjustments used above in the diagram 460 may still be used to reduce or eliminate the non-deterministic quadrature error of the full frequency clock signal 482. For instance, the full-frequency clock signal 482 may be divided (e.g., via the 4-phase cock divider 204) into four divided clock signals, including a clock signal 484 for 0-degree phase, a clock signal 486 for 90-degree phase, a clock signal 488 for 180-degree phase, and a clock signal 490 for 270-degree phase. Similar to the diagram 460, the four divided clock signals may have phase-to-phase misalignments. The clock signal 486 and the clock signal 490 may be adjusted using the same phase adjustments, as illustrated in the diagram 460, to generate the adjusted clock signal 486′ and the adjusted clock signal 490′, as illustrated in the diagram 480.

For example, the phase adjustment mrDCA90D for the clock signal 486 is the same as for the clock signal 442 in the diagram 460, resulting in the adjusted clock signal 486′ with Δt1=5−1=4. The phase adjustment mrDCA180D for the clock signal 488 is the same as the phase adjustment for the clock signal 484 (e.g., mrDCA180D=0), resulting in the clock signal 488 unchanged with Δt2=4−(−1)=5. The phase adjustment mrDCA270D for the clock signal 490 is the same as the phase adjustment mrDCA90D for the clock signal 486, resulting in the adjusted clock signal 490′ with Δt3=5−1=4, as illustrated in the diagram 480. The adjusted clock signals 486′ and 490′ may be used together with the clock signals 484 and 488 to obtain a reconstructed full-frequency clock signal 492 (e.g., by using the rising edges of corresponding pulses of the four divided clock signals). The first clock cycle of the reconstructed full-frequency clock signal 492 may include a high pulse lasting 4 time units and a low pulse lasting 5 time units, and the second clock cycle of the clock signal 492 may include a high pulse lasting 4 time units and a low pulse lasting 3 time units. Therefore, the total two-cycle high corresponds to 8 time units and the total two-cycle low corresponds to 8 time units, with the smallest pulse including 3 time units. Accordingly, the reconstructed full-frequency clock signal 492 may have improved phase and duty cycle compared to the clock signal 482. Accordingly, the two-phase tuning settings may be used to reduce or eliminate the deterministic quadrature error and the non-deterministic quadrature error of a full frequency clock signal.

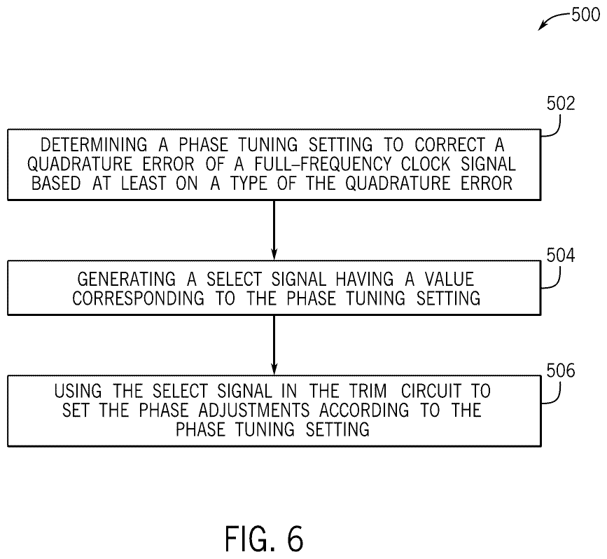

FIG. 6 illustrates a flow diagram of a method 500 for using the trim circuit 119 to reduce or eliminate a quadrature error of a full-frequency clock signal (e.g., the full-frequency clock signal 422). At block 502, a phase tuning setting may be determined based at least on a type of the quadrature error. In some embodiments, the per-phase tuning may be used to correct a deterministic quadrature error due to independent phase-to-phase adjustments used in the per-phase tuning may help to correct the deterministic quadrature error faster than the two-phase tuning, as illustrated in FIGS. 4A-4C. In some embodiments, the two-phase tuning may be used to correct an unknown quadrature error since the two-phase tuning may improve the phase and the duty cycle for both the deterministic quadrature error and the non-deterministic quadrature error, as illustrated in FIGS. 5A and 5B. In some embodiments, the two-phase tuning may be used to correct a non-deterministic quadrature error since the two-phase tuning may improve the phase and the duty cycle for the non-deterministic quadrature error, as illustrated in the diagram 480. At block 504, a select signal (e.g., the select signal 272) may be generated (e.g., by a fuse) and having the value corresponding to the phase tuning setting determined at block 502 (e.g., 0 for per-phase tuning, 1 for two-phase tuning) according to the table 260. At block 506, the select signal (e.g., the select signal 272) may be used in the trim circuit 119 to set the phase adjustments (e.g., mrDCA90D, mrDCA180D, mrDCA270D) for the DCA 250 according to the phase tuning setting in the table 260 to correct the quadrature error, as illustrated in FIGS. 3-5.

Accordingly, the technical effects of the present disclosure include a technology and methods related to phase and duty cycle trimming to reduce or eliminate a quadrature error of a clock signal in a memory device. The memory device may employ a trim circuit to perform phase tuning to reduce or eliminate the quadrature error. Different phase tuning settings may be used by the trim circuit for different types of quadrature errors. The trim circuit may adjust different phases of the clock signal independently or dependently based on the phase tuning settings.

In the illustrated embodiments above, the memory devices and systems are primarily described in the context of devices incorporating DRAM storage media. Memory devices configured in accordance with other embodiments of the present technology, however, may include other types of memory devices and systems incorporating other types of storage media, including PCM, SRAM, FRAM, RRAM, MRAM, read only memory (ROM), erasable programmable ROM (EPROM), electrically erasable programmable ROM (EEROM), ferroelectric, magnetoresistive, and other storage media, including non-volatile, flash (e.g., NAND and/or NOR) storage media. It should be noted that the present technology may also be used in the of High Band Memory (HBM), such as HBM3, HBM4, etc.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents, and alternatives falling within the spirit and scope of the invention as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function]. . . ” or “step for [perform]ing [a function]. . . ”, it is intended that such elements are to be interpreted under 35 U.S.C. 112(f). However, for any claims containing elements designated in any other manner, it is intended that such elements are not to be interpreted under 35 U.S.C. 112(f).

1. A trim circuit, comprising:
a control circuit configured to:
receive a select signal to select a type of phase tuning for a plurality of phase clock signals of a clock signal; and
generate a plurality of phase adjustment signals for the plurality of phase clock signals of the clock signal based on the select signal; and
a duty cycle adjuster (DCA) configured to:
receive the plurality of phase adjustment signals from the control circuit; and
use the plurality of phase adjustment signals to adjust the plurality of phase clock signals.

2. The trim circuit of claim 1, wherein a first value of the select signal corresponds to a first type of phase tuning, in which the plurality of phase adjustment signals are independent to each other.

3. The trim circuit of claim 2, wherein the plurality of phase adjustment signals comprises a first phase adjustment for a first phase clock signal of the clock signal, a second phase adjustment for a second phase clock signal, having a phase difference of 90 degrees from the first phase clock signal, of the clock signal, and a third phase adjustment for a third phase clock signal, having the phase difference of 90 degrees from the second phase clock signal, of the clock signal.

4. The trim circuit of claim 2, wherein the clock signal comprises a deterministic quadrature error.

5. The trim circuit of claim 2, wherein a second value of the select signal corresponds to a second type of phase tuning, in which at least two of the plurality of phase adjustment signals are equal to each other.

6. The trim circuit of claim 5, wherein the plurality of phase adjustment signals comprises a first phase adjustment for a first phase clock signal of the clock signal, a second phase adjustment for a second phase clock signal, having a phase difference of 90 degrees from the first phase clock signal, of the clock signal, and a third phase adjustment for a third phase clock signal, having the phase difference of 90 degrees from the second phase clock signal, of the clock signal.

7. The trim circuit of claim 6, wherein the first phase adjustment is equal to the third phase adjustment.

8. The trim circuit of claim 6, wherein the second phase adjustment is equal to a fourth phase adjustment for a fourth phase clock signal of the clock signal, wherein the first phase clock signal has the phase difference of 90 degrees from the fourth phase clock signal.

9. The trim circuit of claim 5, wherein the clock signal comprises a non-deterministic quadrature error.

10. A method, comprising:
determining a phase tuning setting to correct a quadrature error of a clock signal;
generating a select signal corresponding to the phase tuning setting; and
generating a plurality of phase adjustments signals by using the select signal.

11. The method of claim 10, wherein the phase tuning setting is determined based on a type of the quadrature error.

12. The method of claim 10, wherein a first value of the select signal corresponds to a first type of phase tuning, in which the plurality of phase adjustment signals are independent to each other.

13. The method of claim 12, wherein the clock signal comprises a deterministic quadrature error.

14. The method of claim 11, wherein a second value of the select signal corresponds to a second type of phase tuning, in which at least two of the plurality of phase adjustment signals are equal to each other.

15. The method of claim 14, wherein the clock signal comprises a non-deterministic quadrature error.

16. An apparatus, comprising:
a 4-phase clock divider configured to divide a clock signal into four divided clock signals having respective phases: and
a trim circuit configured to adjust the four divided clock signals using respective phase adjustments generated for the four divided clock signals based on an error of the clock signal.

17. The apparatus of claim 16, wherein the respective phase adjustments are independent to each other when the error comprises a deterministic quadrature error.

18. The apparatus of claim 16, wherein at least two of the respective phase adjustments are equal when the error comprises a non-deterministic quadrature error.

19. The apparatus of claim 18, wherein the respective phase adjustments comprise a first phase adjustment for a first phase clock signal of the clock signal, a second phase adjustment for a second phase clock signal, having a phase difference of 90 degrees from the first phase clock signal, of the clock signal, and a third phase adjustment for a third phase clock signal, having the phase difference of 90 degrees from the second phase clock signal, of the clock signal, and wherein the first phase adjustment is equal to the third phase adjustment.

20. The apparatus of claim 19, wherein the second phase adjustment is equal to a fourth phase adjustment for a fourth phase clock signal of the clock signal, wherein the first phase clock signal has the phase difference of 90 degrees from the fourth phase clock signal.
